(19) United States
(12) Patent Application Publication
(10) Pub. No.: US 2024/0332289 A1
(43) Pub. Date: Oct. 3, 2024

(54) SEMICONDUCTOR INTEGRATED CIRCUIT

(71) Applicant: ROHM CO., LTD., Kyoto-shi (JP)

(72) Inventor: Tatsuro SHIMIZU, Kyoto-shi (JP)

(21) Appl. No.: 18/618,485

(22) Filed: Mar. 27, 2024

(30) Foreign Application Priority Data
Mar. 30, 2023 (JP) 2023-056551

(51) Int. Cl. H01L 27/06; G01R 19/165

(52) U.S. Cl. CPC H01L 27/0682; G01R 19/16504

(57) ABSTRACT

The present disclosure provides a semiconductor integrated circuit. The semiconductor integrated circuit includes a set pin. An external resistor and an external capacitor are connected in parallel between the set pin and an external fixed voltage line. A parameter acquisition circuit is connected to the set pin to obtain a first parameter and a second parameter defined by a resistive value of the external resistor and a capacitive value of the external capacitor.

### CROSS REFERENCE TO RELATED APPLICATIONS

The present invention claims priority under 35 U.S.C. § 119 to Japanese Application No. 2023-056551, filed on Mar. 30, 2023, the entire contents of which being incorporated herein by reference.

### TECHNICAL FIELD

The present disclosure relates to a semiconductor integrated circuit.

### BACKGROUND

It is desired in industry to set parameters primarily such as the operation mode, status, and response speed of a semiconductor integrated circuit (hereinafter collectively referred to as parameters) can be set from the outside of the semiconductor integrated circuit. The setting above can be performed easily if interfaces such as Is Universal Asynchronous Receiver/Transmitter (UART) and I2C are used. However, interfaces corresponding to UART and I2C also need to be prepared for a control target on the outside of the semiconductor integrated circuit, and this can be infeasible according to applications.

As an alternative approach without involving interfaces such as the UART or I2C, sometimes a pin for setting (referred to as a set pin) is provided in a semiconductor integrated circuit, and the approach for setting can be changed according to an electrical state of the set pin.

For example, a voltage corresponding to a set value is applied to the set pin. The semiconductor integrated circuit measures the voltage value and changes the set value. Alternatively, an external resistor having a resistive value corresponding to the set value is connected to the set pin. The semiconductor integrate circuit measures the resistive value and changes the set value according to the measured resistive value.

In such an approach of using the set pin, only one parameter can be set for each set pin. Therefore, if there are multiple parameters to be set, the number of set pins increases by the number of parameters. There may not be enough space to add more pins according to types of packages.

### PRIOR ART DOCUMENT

### Patent Publication

[Patent document 1] Japan Patent Publication No. 2013-271022

### BRIEF DESCRIPTION OF THE DRAWINGS

FIG. 1 is a circuit diagram of a semiconductor integrated circuit according to an embodiment.

FIG. 2 is a circuit diagram of a parameter acquisition circuit of a first embodiment.

FIG. 3 is a waveform diagram of the operation of the parameter acquisition circuit in FIG. 2.

FIG. 4 is a circuit diagram of a configuration example of a measurement circuit.

FIG. 5 is a circuit diagram of another configuration example of a measurement circuit.

FIG. 6 is a circuit diagram of a parameter acquisition circuit of an embodiment.

FIG. 7 is a diagram of the operation of the parameter acquisition circuit in FIG. 6.

FIG. 8 is a circuit diagram of a configuration example of the measurement circuit in FIG. 7.

### DETAILED DESCRIPTION OF THE EMBODIMENTS

### Summary of Embodiments

A summary of several illustrative embodiments of the disclosure is described below. The summary serves as the preamble of the detailed description to be given shortly and aims to provide fundamental understanding of the embodiments by describing several concepts of one or more embodiments in brief. It should be noted that the summary is not to be construed as limitations to the scope of the disclosure. The summary is not a general summary of all conceivable embodiments, nor does it intend to specify important elements of all embodiments or to define the scope of a part of or all aspects. For the sake of better description, “one embodiment” sometimes refers to one embodiment (implementation example or variation example) or multiple embodiments (implementation examples or variation examples) disclosed herein.

A semiconductor integrated circuit according to an embodiment includes: a set pin connected to an external resistor and an external capacitor, wherein the external resistor and the external capacitor are connected in parallel and disposed between the set pin and an external fixed voltage line; and a parameter acquisition circuit, connected to the set pin and configured to acquire a first parameter and a second parameter defined by a resistive value of the external resistor and a capacitive value of the external capacitor.

The external resistor and the external capacitor form a CR circuit. An electrical effect is applied to the CR circuit, and a response of the CR circuit is measured. The response is associated with a resistive value R of the external resistor and a capacitive value C of the external capacitor, and thus the first parameter and the second parameter can be set according to the measured response. The so-called fixed voltage line refers to a voltage line generating a known voltage, for example, a ground line or a power supply line, and is considered a line with a sufficiently low impedance.

In one embodiment, the parameter acquisition circuit can include: a current source, configured to supply a current to the set pin; and a measurement circuit, configured to obtain the first parameter and the second parameter based on a waveform of a voltage generated at the set pin.

A combined impedance Z of the external resistor and the external capacitor is acquired according to

Z=R/(1+jωCR) Equation (1)

For the combined impedance Z, if a known current I is supplied to the impedance Z, a response of a voltage V thereof measured is V=I×Z. Thus, information associated with the impedance Z can be obtained according to the known current I and the measured voltage V. If the measuring is performed according to modified conditions, R and C can be acquired.

In one embodiment, the current can also be a constant current I_{DC} in direct current. When the constant current I_{DC} is supplied to the CR circuit, the measured voltage V becomes

V=(1−exp (−t/CR))×R×I_{DC} Equation (2)

Thus, the first parameter and the second parameter corresponding to R and C can be acquired according to the voltage response.

In one embodiment, the measurement circuit can also obtain the first parameter according to a peak level (a maximum value) of the voltage generated at the set pin. By substituting t=∞ into equation (2), a peak level V_{MAX} of the voltage at the set pin becomes

V_{MAX}−V(∞)=I_{DC}×R Equation (3),
and is proportional to the resistive value R. Thus, the first parameter can be obtained according to the peak level V_{MAX}.

In one embodiment, the measurement circuit can also obtain the second parameter based on a time for the voltage generated at the set pin to reach a threshold value obtained by multiplying the peak level by a predetermined coefficient. For example, the predetermined coefficient can be set to 1/e, and in this case, the time to reach the threshold value becomes CR. Thus, the second parameter associated with C can be obtained using the acquired R.

In one embodiment, the measurement circuit can further include a plurality of comparators configured to compare the voltage generated at the set pin with different thresholds, and a decoder circuit.

In one embodiment, the measurement circuit can further include an analog-to-digital (A/D) converter, and a digital processing circuit configured to process an output of the A/D converter. Moreover, the digital processing circuit is not limited to a processor capable of executing software programs but can also be a hardware logic (a layout logic).

In one embodiment, the current can also be an alternating current in a single frequency. If the alternating current is set to I_{AC}=I·sin ωt, then

V=Z×I_{AC}=R/(1+jωCR)×I·sinωt Equation (4).

R and C can be obtained according to the known current I_{AC} and the measured voltage V.

In one embodiment, the measurement circuit can also obtain the first parameter according to an amplitude of the voltage generated at the set pin.

In one embodiment, the measurement circuit can also obtain the second parameter according to a phase difference between the voltage generated at the set pin and the current.

In one embodiment, the measurement circuit can further include an A/D converter, and a digital processing circuit configured to process an output of the A/D converter.

### Embodiments

Details of the preferred embodiments are described with the accompanying drawings below. The same or equivalent constituting elements, parts and processes shown in the accompanying drawings are represented by the same denotations, and repeated description is omitted as appropriate. It should be noted that the embodiments are examples rather than limitations to the present disclosure, and all features or combinations thereof described in the embodiments are not necessarily limited to the disclosure and are not necessarily essentials of the disclosure.

In the detailed description of the present application, an expression “a state of a component A connected to a component B” includes a situation where the component A and the component B are directly connected, or a situation where the component A is indirectly connected to the component B via another component, and the indirect connection does not result in substantial influences on their electrical connection or does not impair functions or effects exerted by their connection.

Similarly, an expression “a state of a component C arranged between a component A connected to a component B” includes, in addition to a situation where the component A and the component C, or the component B and component C are directly connected, an indirect connection via another component, and the indirect connection does not result in substantial influences on their electrical connection or does not impair functions or effects exerted by their connection.

### Embodiments

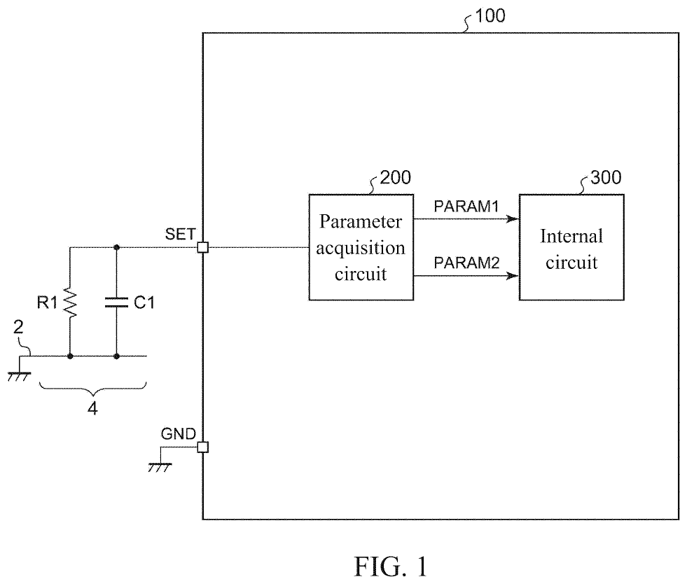

FIG. 1 shows a circuit diagram of a semiconductor integrated circuit 100 according to an embodiment. The semiconductor integrated circuit 100 includes a set pin SET, a parameter acquisition circuit 200 and an internal circuit 300. The set pin SET is provided to set parameters such as operating conditions and operating mode of the internal circuit 300 of the semiconductor integrated circuit 100 from the outside. The configuration, function and type of the internal circuit 300 are not specifically defined. An external resistor R1 and an external capacitor C1 are connected in parallel between the set pin SET and a fixed voltage line 2. The fixed voltage line 2 is, for example, a ground line.

The parameter acquisition circuit 200 is connected to the set pin SET and obtains a first parameter PARAM1 and a second parameter PARAM2 defined by a resistive value R of the external resistor R1 and a capacitive value C of the external capacitor C1.

Alternatively, the resistive value R and the first parameter PARAM1 can be in one-to-one correspondence, and the capacitive value C and the second parameter PARAM2 can be in one-to-one correspondence.

That is, the relationships PARAM1=f(R) and PARAM2=g(C) are satisfied. In the above, f( ) and g( ) are any desired functions or images.

Alternatively, a combination of the resistive value R and the capacitive value C can also individually define the first parameter PARAM1 and the second parameter PARAM2: PARAM1=f(R, C) and PARAM2=g(R, C).

In the above, f and g are functions or images of 2 variables.

The configuration of the semiconductor integrated circuit 100 is as described above. Next, a CR circuit 4 is formed by the external resistor R1 and the external capacitor C1. The parameter acquisition circuit 200 applies an electrical effect on the CR circuit 4 and measures a response of the CR circuit 4. The response is associated with the resistive value R of the external resistor R1 and the capacitive value C of the external capacitor C1, and thus the first parameter PARAM1 and the second parameter PARAM2 can be set according to the measured response.

More specifically, a combined impedance of the CR circuit 4 is represented by

Z=R/(1+jωCR) Equation (1).

Thus, if a current signal is applied to the combined impedance Z and a response of a voltage signal is measured, information associated with the impedance Z can be obtained, and R and C can then be measured. Alternatively, a response of a current signal can also be measured by applying a voltage signal to obtain information associated with the impedance Z.

The operation of the semiconductor integrated circuit 100 is as described above. According to the semiconductor integrated circuit 100, the single set pin SET can be used to set two independent parameters PARAM1 and PARAM2.

The present disclosure is understood as the circuit diagram of FIG. 1 or relates to various devices and methods derived from the above description and is not limited to any specific configuration. To help better and more clearly understand the essentials and operations of the disclosure but not to narrow the scope of the disclosure, more specific configuration examples and embodiments are described below.

### First Embodiment

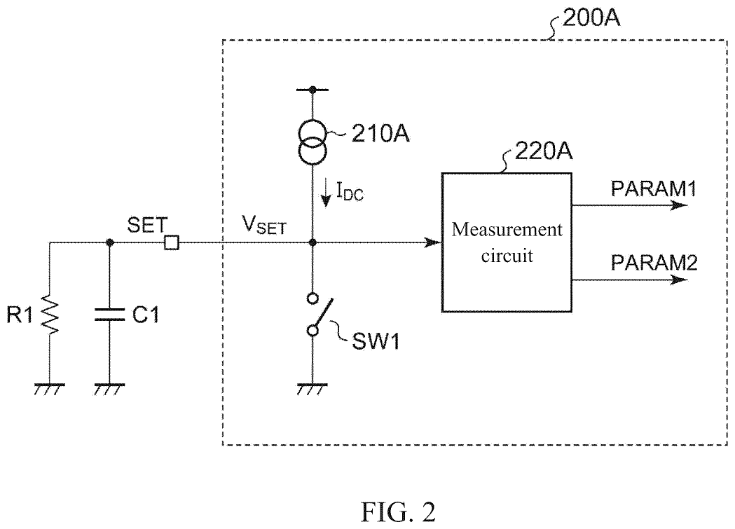

FIG. 2 is a circuit diagram of a parameter acquisition circuit 200A of the first embodiment. The parameter acquisition circuit 200A includes a current source 210A, a switch SW1 and a measurement circuit 220A.

The current source 210A is connected to the set pin SET and generates a constant current I_{DC} in direct current. The measurement circuit 220A obtains the first parameter PARAM1 and the second parameter PARAM2 according to a waveform of a voltage V_{SET} generated at the set pin SET.

The switch SW1 is provided to initialize the voltage V_{SET} at the set pin SET and is turned on before the voltage V_{SET} is measured and turned off while the voltage V_{SET} is being measured. Moreover, in a case that on and off of the current source 210A can be switched, when the current source 210A is off, charge is released from the capacitor C1 due to the externally installed resistor R1, and accordingly the voltage V_{SET} is initialized. Thus, by configuring a measurement sequence, the switch SW1 can also be omitted. Alternatively, in a case where the current source 210A is configured to be able to source and sink a current, by sinking a current from the current source 210A, the voltage V_{SET} can be reset to 0 V, and the switch SW1 can then also be omitted.

A current amount of the direct current I_{DC} is set as I. If the switch SW1 is switched from on to off, by applying a stepped direct current I_{DC} to the CR circuit 4, the voltage VSET with a step response to the CR circuit 4 appears at the set pin SET. That is to say, the voltage V_{SET} is represented by equation (2).

V_{SET}=(1−exp (−t/CR))×R×I_{DC} Equation (2)

Thus, by measuring the voltage V_{SET} by the measurement circuit 220A, the resistive value R and the capacitive value C can be measured, and the parameters PARAM1 and PARAM2 can be obtained.

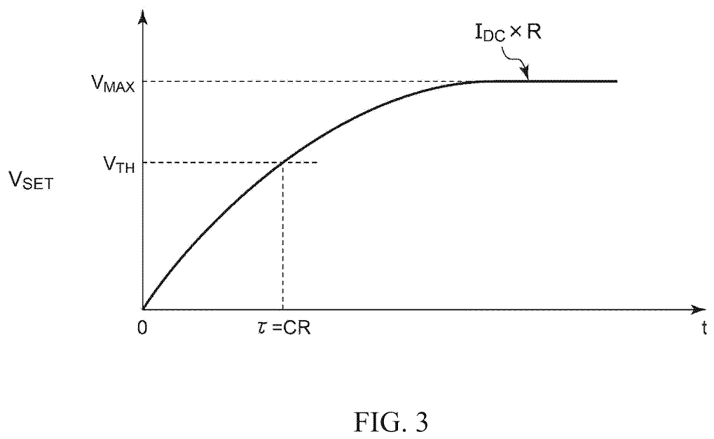

FIG. 3 shows a waveform diagram of the operation of the parameter acquisition circuit 200A in FIG. 2. By substituting t=∞ into equation (2), the peak level V_{MAX} of the voltage at the set pin is obtained and becomes

V_{MAX}−V(∞)=I_{DC}×R Equation (3).

Thus, the measurement circuit 220 obtains the first parameter PARAM1 according to the peak level V_{MAX} of the voltage V_{SET} generated at the set pin SET.

Moreover, the measurement circuit 220 obtains the second parameter PARAM2 based on a time for the voltage V_{SET} generated at the set pin SET to reach a threshold value VTH obtained by multiplying the peak level V_{MAX} by the predetermined coefficient α.

V_{TH}=α×V_{MAX}

For example, α=(1−1/e) can be adopted. In this case, the time t for the set voltage V_{SET} to reach the threshold value V_{TH} becomes τ=CR. Thus, by dividing the measured time t by the obtained resistive value R, the capacitive value C can be obtained. Alternatively, the measured time constant CR can also be set as the second parameter PARAM2.

A specific configuration example of the measurement circuit 220 is described below.

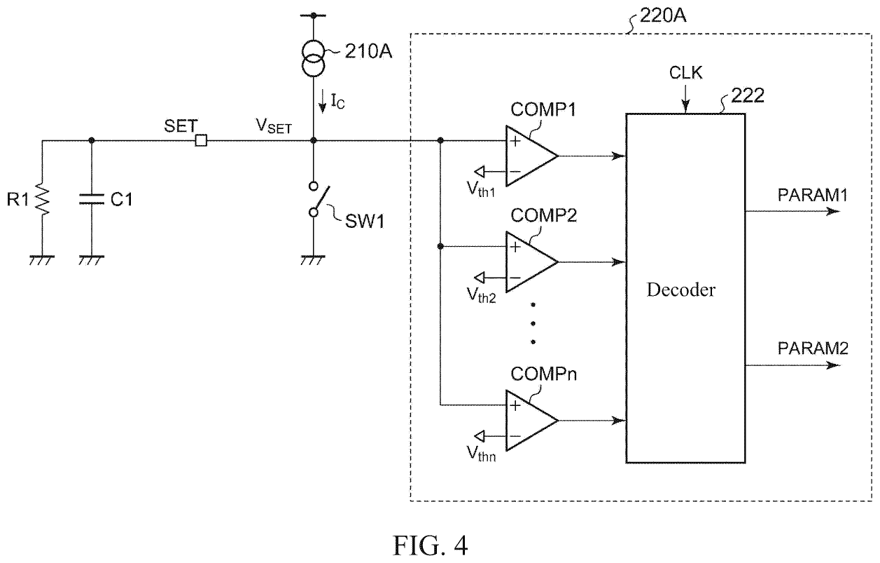

FIG. 4 shows a circuit diagram of a configuration example of a measurement circuit 220A. The measurement circuit 220A includes a plurality of (n in quantity) comparators COMP1 to COMPn, and a decoder circuit 222. The first parameter PARAM1 can be set from n+1 values.

The plurality of comparators COMP1 to COMPn compare the voltage V_{SET} at the set pin SET with different threshold voltages Vth1 to Vthn (Vth1<Vth2<. . . . Vthn). The decoder circuit 222 monitors output signals S1 to Sn of the plurality of comparators COMP1 to COMPn, and detects values (1, 0) thereof and change timings of the values.

After a sufficient time has elapsed from when the switch SW1 is turned off, it is set that S1 to Sj=1, and Sj+1 to Sn=0. In this case, the maximum value V_{MAX} of the voltage V_{SET} at the set pin SET is Vthj<V_{MAX}<Vthj+1. Thus, the value of the first parameter PARAM1 is obtained as j. In addition, the resistive value R is calculated as R=Vthj/I.

Next, the kth threshold voltage Vthk among the threshold voltages Vth1 to Vthn is made closest to the voltage level obtained by multiplying the maximum value V_{MAX} by the coefficient a. In this case, the change time τ of the output Sk of the comparator COMPk corresponds to the time constant CR. By dividing the time τ by the resistive value R, the capacitive value C can be obtained.

Moreover, without having to calculate the resistive value R or the capacitive value C, the measurement circuit 220A is required to only perform necessary minimal processing to specify the first parameter PARAM1 and the second parameter PARAM2.

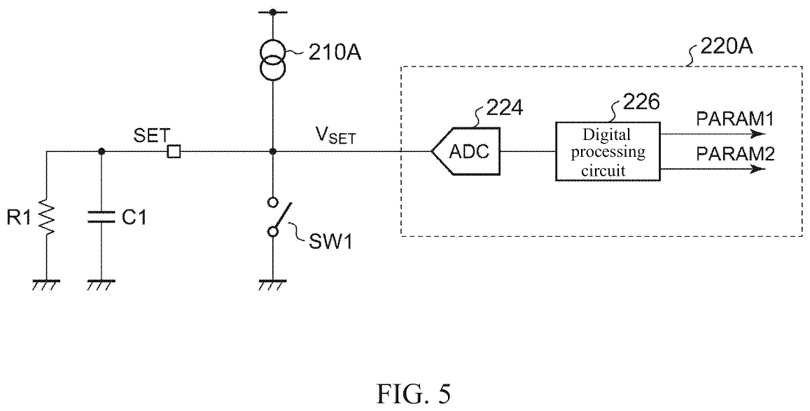

FIG. 5 shows a circuit diagram of a configuration example of another measurement circuit 220A. The measurement circuit 220A includes an analog-to-digital (A/D) converter 224 and a digital processing circuit 226. The A/D converter 224 samples at a predetermined frequency to convert the voltage V_{SET} at the set pin SET to a digital signal. An output of the A/D converter 224 becomes waveform data WAVE of the voltage V_{SET} at the set pin SET. The digital processing circuit 226 processes the waveform data WAVE to calculate the resistive value R and the capacitive value C, and to specify the first parameter PARAM1 and the second parameter PARAM2.

### Second Embodiment

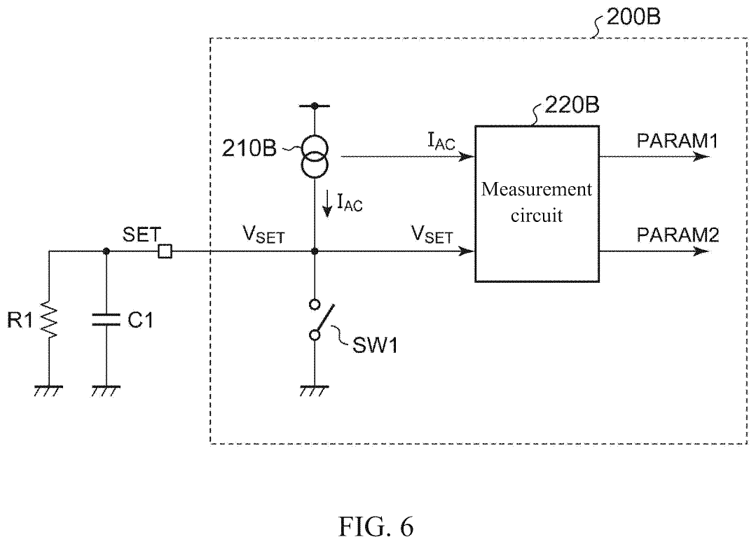

FIG. 6 shows a circuit diagram of a parameter acquisition circuit 200B of one embodiment. The parameter acquisition circuit 200B includes a current source 210B, a switch SW1 and a measurement circuit 220B. Similar to the first embodiment, the measurement circuit 220B obtains the first parameter PARAM1 and the second parameter PARAM2 according to the waveform of the voltage V_{SET} generated at the set pin SET.

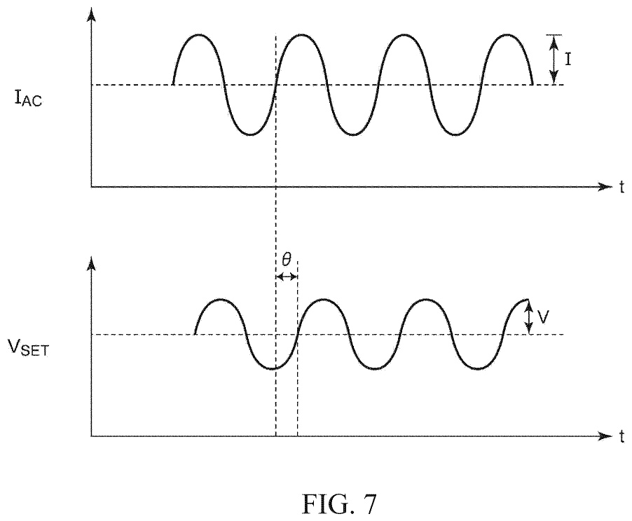

FIG. 7 shows a diagram of the operation of the parameter acquisition circuit 200B in FIG. 6.

The current source 210B is connected to the set pin SET and generates an alternating current I_{AC} that is applied to the CR circuit 4. The alternating current I_{AC} can also include a single sine wave of frequency ω.

I_{AC}=I·sinωt Equation (4)

A result of the alternating current I_{AC} applied to the CR circuit 4 provides a voltage response V_{SET} according to equation (5) below.

V_{SET}=Z×I·sinωt Equation (5)

The voltage response V_{SET} is a sine wave signal and is represented by equation (6).

V_{SET=V}·sin (ωt+θ) Equation (6)

The measurement circuit 220B measures a voltage amplitude V and a phase difference θ. The measurement circuit 220B can also calculate a magnitude |Z| of the impedance Z by dividing the amplitude V of the voltage V_{SET} by a current amplitude I.

|Z|=V/I

The magnitude |Z| of the impedance Z is

|Z|=1/\sqrt{(R⁻²+w²C²)} Equation (7)

Moreover, the phase difference θ is obtained according to equation (8).

θ=arctan(−ωCR) Equation (8)

The measurement circuit 220B can also obtain the first parameter PARAM1 according to |Z|, and obtain the second parameter PARAM2 according to θ.

Alternatively, the resistive value R and the capacitive value C can also be obtained according to equations (7) and (8), the first parameter PARAM1 is obtained according to the resistive value R, and the second parameter PARAM2 is obtained according to the capacitive value C.

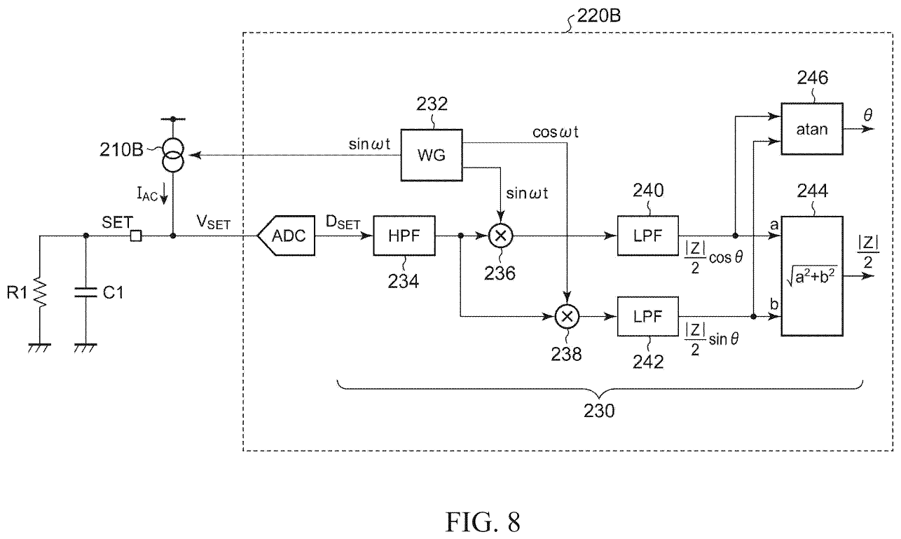

FIG. 8 shows a circuit diagram of a configuration example of the measurement circuit 220B in FIG. 7. The measurement circuit 220B includes an A/D converter 228 and a digital processing circuit 230.

The A/D converter 228 converts the voltage V_{SET} at the set pin SET to a digital signal D_{SET}.

The digital processing circuit 230 includes a waveform generator 232, a high-pass filter 234, multipliers 236 and 238, low-pass filters 240 and 242, and operation units 244 and 246.

The waveform generator 232 generates waveform data of a sine wave sinot. The current source 210B is a current DAC and changes the waveform data of the sine wave sinot to a current signal I_{AC}. Moreover, the current signal I_{AC} can also include a direct-current (DC) bias component IDC, and in this case, the above can be represented as I_{AC}=I_{DC}+I·sinωt.

The high-pass filter 234 removes frequency components other than the frequency ω from the digital signal D_{SET}. An output of the high-pass filter 234 is represented as V·sin(ωt+θ).

In addition to outputting the waveform data of the sine wave sinot, the waveform generator 232 further outputs waveform data of a cosine wave cost.

The multiplier 236 multiplies an output I·sin(ωt+θ) of the high-pass filter 234 by the sine wave sinωt. An output of the low-pass filter 240 is represented as a=|Z|/2·cosθ.

The multiplier 238 multiplies the output I·sin(ωt+θ) of the high-pass filter 234 by the cosine wave cosωt. An output b of the low-pass filter 242 is represented as b=|Z|/2·sinθ. The operation unit 244 calculates |Z|/2=(a²+b²).

The operation unit 246 calculates θ=arctan (a/b).

A backend processing circuit can specify the parameters PARAM1 and PARAM2 according to |Z| and θ.

It should be understood that the embodiments are exemplary, and various modifications may be made to combinations of the constituting elements and processes, and such modifications are encompassed within the present disclosure or the scope of the present disclosure.

### Variation Example 1

In the embodiment, the fixed voltage line 2 configured as a ground line is described; however, a power supply line can also be used as the fixed voltage line. In this case, the parameter acquisition circuit 200 only needs to be configured to be in a top-down inverted structure to that of the circuit described in the embodiment.

### Variation Example 2

In the parameter acquisition circuit 200B in FIG. 6, when the current I_{AC} includes a DC bias component, the measurement circuit 220B can also use a low-pass filter to obtain a DC component of the voltage signal VSET, and obtain the resistive value R according to the DC component.

### Note

The technology disclosed in this specification can be understood as follows.

### Item 1

A semiconductor integrated circuit, comprising:
   a set pin connected to an external resistor and an external capacitor, wherein the external resistor and the external capacitor are connected in parallel and disposed between the set pin and an external fixed voltage line; and
   a parameter acquisition circuit, connected to the set pin and configured to acquire a first parameter and a second parameter defined by a resistive value of the external resistor and a capacitive value of the external capacitor.

### Item 2

The semiconductor integrated circuit of Item 1, wherein the parameter acquisition circuit includes:
   a current source, configured to supply a current to the set pin;
   a measurement circuit, configured to obtain the first parameter and the second parameter based on a waveform of a voltage generated at the set pin.

### Item 3

The semiconductor integrated circuit of Item 2, wherein the current is a constant current in direct current.

### Item 4

The semiconductor integrated circuit of Item 3, wherein the measurement circuit is configured to obtain the first parameter according to a peak level of the voltage generated at the set pin.

### Item 5

The semiconductor integrated circuit of Item 3 or 4, wherein the measurement circuit is configured to obtain the second parameter based on a time for the voltage generated at the set pin to reach a threshold value obtained by multiplying the peak level by a predetermined coefficient.

### Item 6

The semiconductor integrated circuit of any one of Items 3 to 5, wherein the measurement circuit includes:
   a plurality of comparators, configured to compare the voltage generated at the set pin with different thresholds; and
   a decoder circuit, configured to process outputs of the plurality of comparators.

### Item 7

The semiconductor integrated circuit of any one of Items 3 to 5, wherein the measurement circuit includes:
   an A/D converter; and
   a digital processing circuit, configured to process an output of the A/D converter.

### Item 8

The semiconductor integrated circuit of Item 2, wherein the current is an alternating current in a single frequency.

### Item 9

The semiconductor integrated circuit of Item 8, wherein the measurement circuit is configured to obtain the first parameter according to an amplitude of the voltage generated at the set pin.

### Item 10

The semiconductor integrated circuit of Item 8 or 9, wherein the measurement circuit is configured to obtain the second parameter according to a phase difference between the voltage generated at the set pin and the current.

### Item 11

The semiconductor integrated circuit of any one of Items 8 to 10, wherein the measurement circuit includes:
   an A/D converter; and
   a digital processing circuit, configured to process an output of the A/D converter.

1. A semiconductor integrated circuit, comprising:
a set pin connected to an external resistor and an external capacitor, wherein the external resistor and the external capacitor are connected in parallel and disposed between the set pin and an external fixed voltage line; and
a parameter acquisition circuit, connected to the set pin and configured to acquire a first parameter and a second parameter defined by a resistive value of the external resistor and a capacitive value of the external capacitor.

2. The semiconductor integrated circuit of claim 1, wherein the parameter acquisition circuit includes:
a current source, configured to supply a current to the set pin;
a measurement circuit, configured to obtain the first parameter and the second parameter based on a waveform of a voltage generated at the set pin.

3. The semiconductor integrated circuit of claim 2, wherein the current is a constant current in direct current.

4. The semiconductor integrated circuit of claim 3, wherein the measurement circuit is configured to obtain the first parameter according to a peak level of the voltage generated at the set pin.

5. The semiconductor integrated circuit of claim 3, wherein the measurement circuit is configured to obtain the second parameter based on a time for the voltage generated at the set pin to reach a threshold value obtained by multiplying a peak level by a predetermined coefficient.

6. The semiconductor integrated circuit of claim 4, wherein the measurement circuit is configured to obtain the second parameter based on a time for the voltage generated at the set pin to reach a threshold value obtained by multiplying the peak level by a predetermined coefficient.

7. The semiconductor integrated circuit of claim 3, wherein the measurement circuit includes:
a plurality of comparators, configured to compare the voltage generated at the set pin with different thresholds; and
a decoder circuit, configured to process outputs of the plurality of comparators.

8. The semiconductor integrated circuit of claim 4, wherein the measurement circuit includes:
a plurality of comparators, configured to compare the voltage generated at the set pin with different thresholds; and
a decoder circuit, configured to process outputs of the plurality of comparators.

9. The semiconductor integrated circuit of claim 3, wherein the measurement circuit includes:
an A/D converter; and
a digital processing circuit, configured to process an output of the A/D converter.

10. The semiconductor integrated circuit of claim 4, wherein the measurement circuit includes:
an A/D converter; and
a digital processing circuit, configured to process an output of the A/D converter.

11. The semiconductor integrated circuit of claim 2, wherein the current is an alternating current in a single frequency.

12. The semiconductor integrated circuit of claim 11, wherein the measurement circuit is configured to obtain the first parameter according to an amplitude of the voltage generated at the set pin.

13. The semiconductor integrated circuit of claim 11, wherein the measurement circuit is configured to obtain the second parameter according to a phase difference between the voltage generated at the set pin and the current.

14. The semiconductor integrated circuit of claim 12, wherein the measurement circuit is configured to obtain the second parameter according to a phase difference between the voltage generated at the set pin and the current.

15. The semiconductor integrated circuit of claim 11, wherein the measurement circuit includes:
an A/D converter; and
a digital processing circuit, configured to process an output of the A/D converter.

16. The semiconductor integrated circuit of claim 12, wherein the measurement circuit includes:
an A/D converter; and
a digital processing circuit, configured to process an output of the A/D converter.
